(19) United States
(12) Patent Application Publication
(10) Pub. No.: US 2026/0082457 A1
(43) Pub. Date: Mar. 19, 2026

(54) COOKING APPLIANCE WITH ACTIVE COOLING FAN CONTROL FOR OPEN DOOR

(71) Applicant: WHIRLPOOL CORPORATION, BENTON HARBOR, MI (US)

(72) Inventors: Giordano Aielli, Arsago Seprio (VA) (IT); Federico Garuccio, Milan (IT); Claudio Maria Marongiu, Varese (IT); Luca Zilio, Cassinetta (IT)

(73) Assignee: WHIRLPOOL CORPORATION, BENTON HARBOR, MI (US)

(21) Appl. No.: 18/886,322

(22) Filed: Sep. 16, 2024

(51) Int. Cl. H05B 6/64; F24C 15/00; H05K 7/20

(52) U.S. Cl. CPC H05B 6/642; F24C 15/006; H05K 7/20136; H05K 7/20209; H05B 6/647

(57) ABSTRACT

A cooking appliance includes an external enclosure defining an inlet. An electronics area is defined between a top of an internal housing and the external enclosure. A cooling fan is disposed in the electronics area and in fluid communication with the inlet. A temperature sensor is disposed within the electronics area. A door is coupled with the external. The door defines a door inlet fluidly coupled with a door outlet via a door passage. The door outlet is in fluid communication with the inlet when the door is closed. A controller is communicatively coupled with the cooling fan. The controller is configured to activate the cooling fan to draw air through the door passage and into the electronics area when the door is closed, deactivate the cooling fan in response to the door opening, and reactivate the cooling fan in response to a sensed temperature exceeding a predefined temperature.

### BACKGROUND OF THE DISCLOSURE

The present disclosure generally relates to a cooking appliance, and more specifically, to a cooking appliance with active cooling fan control for an opened door.

### SUMMARY OF THE DISCLOSURE

According to one aspect of the present disclosure, a cooking appliance includes an external enclosure defining an interior. The external enclosure defines at least one inlet at an upper portion thereof. An internal housing defines a cooking cavity. The internal housing is disposed within the interior. An electronics area is defined between a top of the internal housing and the external enclosure. A cooling fan is disposed in the electronics area and is in fluid communication with the at least one inlet. A temperature sensor is disposed within the electronics area. A door is operably coupled with the external enclosure for enclosing the cooking cavity. The door defines a door inlet that is fluidly coupled with a door outlet via a door passage. The door outlet is in fluid communication with the at least one inlet when the door is in a closed position. A controller is communicatively coupled with the cooling fan. The controller is configured to activate the cooling fan to draw air through the door passage and into the electronics area when the door is in the closed position, deactivate the cooling fan in response to the door moving to an opened position, and reactivate the cooling fan in response to a sensed temperature sensed by the temperature sensor exceeding a predefined temperature.

According to another aspect of the present disclosure, a combination cooking appliance includes an external enclosure defining a first inlet and a second inlet. An internal housing defines a cooking cavity. An electronics area is defined between the external enclosure and the internal housing proximate to the first and second inlets. At least one cooking component is operably coupled with the cooking cavity. A door is operably coupled with the external enclosure. The door defines a door inlet and a door outlet. The door outlet is in fluid communication with the first inlet. A cooling fan is disposed within the electronics area. A temperature sensor disposed within the electronics area. A controller is communicatively coupled with the cooling fan. The controller is configured to at least one of deactivate the cooling fan and retain the cooling fan in an inactive state in response to the door moving to an opened position, receive a sensed temperature from the temperature sensor, activate the cooling fan when the sensed temperature exceeds a first predefined temperature with the door in the opened position, and deactivate the cooling fan when the sensed temperature reaches a second predefined temperature.

According to yet another aspect of the present disclosure, a method of controlling ventilation of a cooking appliance includes heating a cooking cavity; activating a cooling fan in response to a temperature of the cooking cavity exceeding a predefined cavity temperature; drawing air through a door passage, through an inlet, and into an electronics area with the cooling fan when a door is in a closed position; deactivating the cooling fan in response to the door moving to an opened position; and reactivating the cooling fan in response to a sensed temperature from a temperature sensor within the electronics area exceeding a predefined temperature with the door in the opened position.

These and other features, advantages, and objects of the present disclosure will be further understood and appreciated by those skilled in the art by reference to the following specification, claims, and appended drawings.

### BRIEF DESCRIPTION OF THE DRAWINGS

In the drawings:

FIG. 1 is a side perspective view of a cooking appliance, according to the present disclosure;

FIG. 2 is a side perspective view of a cooking appliance with a door in an opened position, according to the present disclosure;

FIG. 3 is a side perspective view of a cooking appliance with an external enclosure and a door removed, according to the present disclosure;

FIG. 4 is a block diagram of a cooking appliance, according to the present disclosure;

FIG. 5 is a front elevational, cross-sectional view of the cooking appliance of FIG. 1, taken along lines V-V, according to the present disclosure;

FIG. 6 is a side elevational, cross-sectional view of the cooking appliance of FIG. 1, taken along lines VI-VI, according to the present disclosure;

FIG. 7 is a side elevational, cross-sectional view of a cooking appliance with a door in an opened position, according to the present disclosure;

FIG. 8 is a graph representative of a cavity temperature and sensed temperatures of electronic components for a cooking appliance over time, according to the present disclosure;

FIG. 9 is a graph illustrating cavity temperature for a cooking appliance over time, according to the present disclosure;

FIG. 10 is a graph illustrating sensed temperatures for a cooking appliance over time before and after each of a door opening event and a fan activation event, according to the present disclosure; and

FIG. 11 is a flow diagram of a method of controlling ventilation for a cooking appliance, according to the present disclosure.

The components in the figures are not necessarily to scale, emphasis instead being placed upon illustrating the principles described herein.

### DETAILED DESCRIPTION

The present illustrated embodiments reside primarily in combinations of method steps and apparatus components related to a cooking appliance with door-based cooling fan control. Accordingly, the apparatus components and method steps have been represented, where appropriate, by conventional symbols in the drawings, showing only those specific details that are pertinent to understanding the embodiments of the present disclosure so as not to obscure the disclosure with details that will be readily apparent to those of ordinary skill in the art having the benefit of the description herein. Further, like numerals in the description and drawings represent like elements.

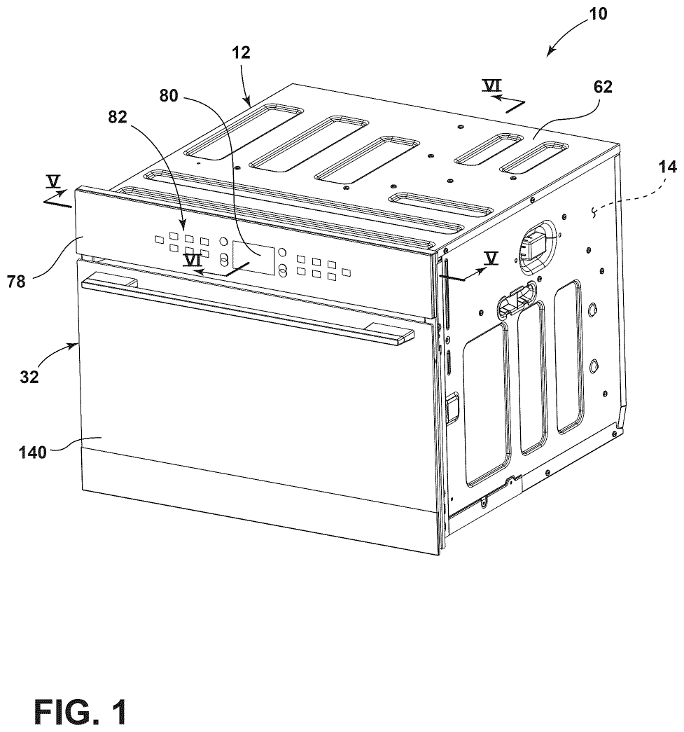

For purposes of description herein, the terms “upper,” “lower,” “right,” “left,” “rear,” “front,” “vertical,” “horizontal,” and derivatives thereof shall relate to the disclosure as oriented in FIG. 1. Unless stated otherwise, the term “front” shall refer to the surface of the element closer to an intended viewer, and the term “rear” shall refer to the surface of the element further from the intended viewer. However, it is to be understood that the disclosure may assume various alternative orientations, except where expressly specified to the contrary. It is also to be understood that the specific devices and processes illustrated in the attached drawings, and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

The terms “including,” “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises a . . . ” does not, without more constraints, preclude the existence of additional identical elements in the process, method, article, or apparatus that comprises the element.

With reference to FIGS. 1-11, reference numeral 10 generally designates a cooking appliance 10, which includes an external enclosure 12 defining an interior 14. The external enclosure 12 defines at least one inlet 16, 18, which generally includes first or upper inlets 16 and second or lower inlets 16, 18. The inlets 16, 18 are defined in an upper, front portion of the external enclosure 12. An internal housing 20 is disposed within the interior 14 and defines a cooking cavity 22. An electronics space or area 24 is defined between a top 26 of the internal housing 20 and the external enclosure 12. A cooling fan 28 is disposed in the electronics area 24 and is in fluid communication with the inlets 16, 18. A temperature sensor 30 is disposed within the electronics area 24. A door 32 is operably coupled with the external enclosure 12 for enclosing the cooking cavity 22. The door 32 defines at least one and typically multiple door inlets 34. The door inlets 34 are generally defined at sides of the door 32 and are fluidly coupled with at least one and typically multiple door outlets 36 via a door passage 38. The door outlets 36 are in fluid communication with at least one of the inlets 16, 18 of the external enclosure 12 when the door 32 is in a closed position.

A controller 40 is communicatively coupled with the cooling fan 28. The controller 40 is configured to activate the cooling fan 28 to draw air through the door passage 38 and into the electronics area 24 via the lower inlets 18 when the door 32 is in the closed position. The cooling fan 28 is also configured to draw air from an external or surrounding environment through the upper inlets 16. The controller 40 is configured to deactivate the cooling fan 28 or retain the cooling fan 28 in an inactive state in response to the door 32 moving to an opened position. The controller 40 is also configured to reactivate the cooling fan 28 in response to a sensed temperature 42 sensed by the temperature sensor 30 reaching or exceeding a first predefined temperature 44 or temperature range, also referred to herein as an activation temperature 44 or activation temperature range. Additionally, the controller 40 is configured to deactivate the cooling fan 28 when the sensed temperature 42 reaches or falls below a second predefined temperature 46 or temperature range, also referred to herein as a deactivation temperature 46 or deactivation temperature range. The deactivation temperature 46 may be the same as or less than the activation temperature 44.

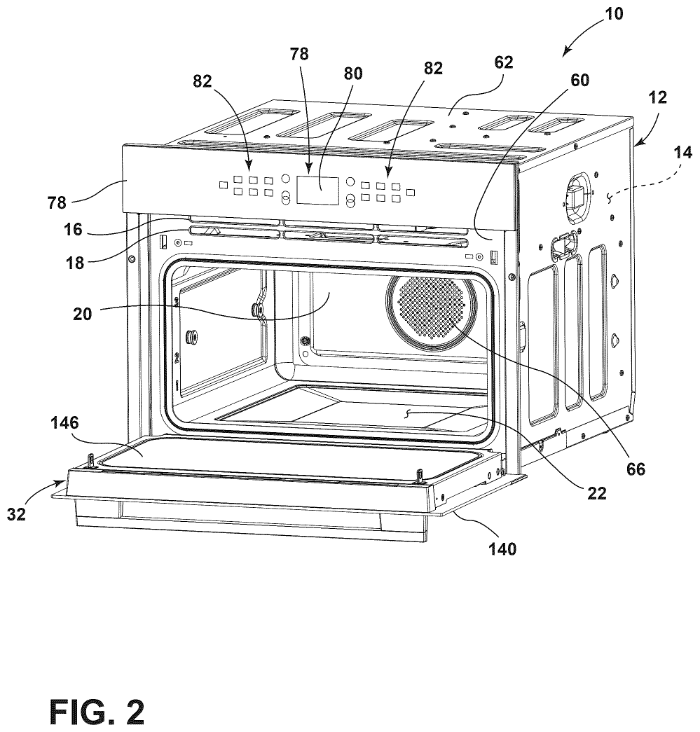

Referring to FIGS. 1 and 2, the cooking appliance 10 includes the external enclosure 12, which is generally formed from a plurality of surfaces or panels, to define the interior 14. The surfaces or panels include a front panel 60, defining an opening into the cooking cavity 22, as well as a top panel 62 enclosing various electronic components 64 in the electronics area 24. The door 32 is operably coupled to the external enclosure 12 at or proximate to the front panel 60 and is configured to move between the closed position, enclosing the cooking cavity 22, and the opened position for accessing the cooking cavity 22. In the illustrated configuration, the door 32 is configured to rotate about a lower horizontal axis. However, it is contemplated that other configurations of the door 32 can be included in the cooking appliance 10, such as multiple doors 32, the door 32 being configured to rotate about an upper horizontal axis, the door 32 being configured to rotate about one or more vertical axes, or the door 32 being configured to slide.

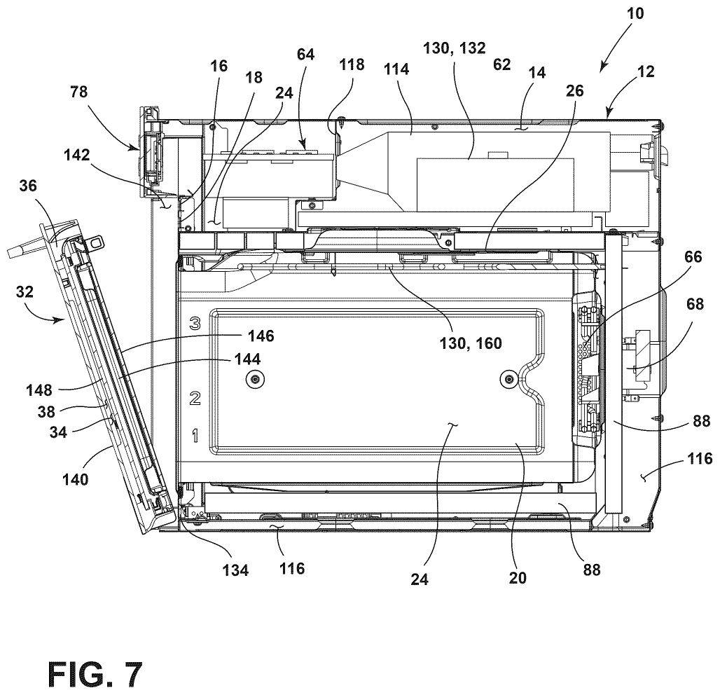

The cooking cavity 22 generally includes one or more cooking levels for positioning racks for holding food items within the cooking cavity 22 to be heated or cooked. The configuration of the cooking cavity 22 may depend on the types of cooking processes provided by the cooking appliance 10. In the illustrated configuration, the cooking cavity 22 defines apertures 66, which may allow for airflow into or through the cooking cavity 22, such as for cooling or cooking processes. For example, a back surface of the internal housing 20 defines the apertures 66 with a circulation fan 68 (FIG. 7) arranged proximate to the apertures 66 between the internal housing 20 and the external enclosure 12 for providing convection and/or air frying cooking processes in the cooking cavity 22.

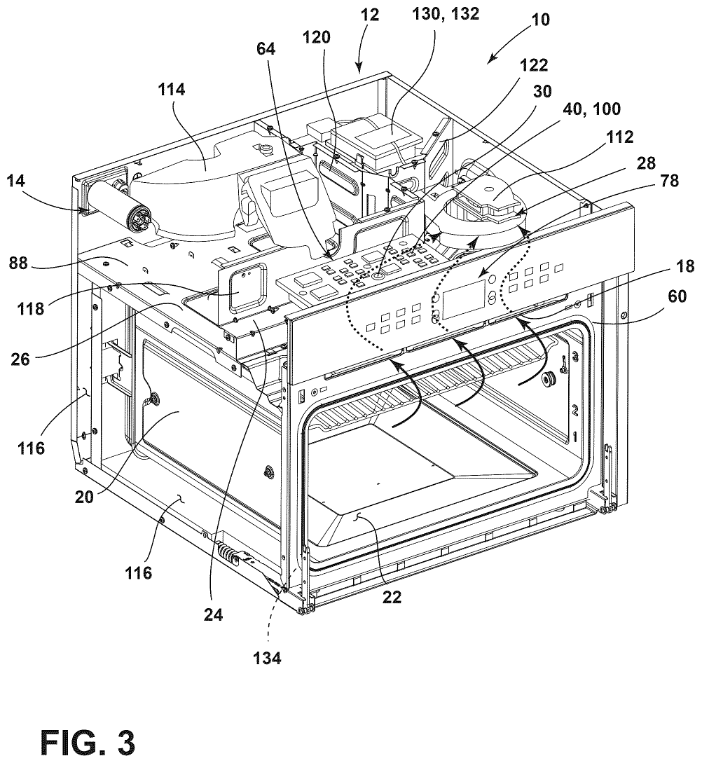

Referring still to FIG. 2, as well as FIG. 3, the front panel 60 defines the upper and lower inlets 16, 18. The upper and lower inlets 16, 18 are arranged adjacent to one another and vertically above the cooking cavity 22. The inlets 16, 18 may be arranged to extend a substantial width of the opening into the cooking cavity 22. In the illustrated configuration, the cooking appliance 10 includes three elongated upper inlets 16 and three elongated lower inlets 18 vertically aligned with one another. Other shapes and configurations for the inlets 16, 18 are contemplated without departing from the teachings herein.

The inlets 16, 18 are generally defined between a top of the opening into the cooking cavity 22 and a user interface 78. Further, the inlets 16, 18 and the opening into the cooking cavity 22 may be defined through a single plane, which is offset or recessed from the user interface 78. The user interface 78 may include a display 80 as well as input controls 82, which may be buttons, toggles, touch features, etc. for controlling the functions of the cooking appliance 10.

The cooking appliance 10 may include an internal panel 88 or multiple internal panels 88 that extend between the internal housing 20 and the external enclosure 12. In certain aspects, the cooking appliance 10 may also include layers of thermal insulation material coupled with internal panels 88 that may assist with reducing heat transfer within a space between the internal housing 20 and the external enclosure 12, including the electronics area 24. Additionally or alternatively, the internal panel(s) 88 may assist with supporting the various electronic components 64, while creating a barrier between the electronic components 64 and the internal housing 20. The electronics area 24 is defined between the internal housing 20 and the external enclosure 12. More particularly, the electronics area 24 is generally arranged in the top portion of the cooking appliance 10 between the top 26 of the internal housing 20 and the top panel 62 of the external enclosure 12. In certain aspects, at least one internal panel 88 can extend between the top 26 of the internal housing 20 and the top panel 62, and the electronics area 24 may be defined between the internal panel 88 and the external enclosure 12. The electronics area 24 is directly or indirectly disposed above the cooking cavity 22.

The location of the electronics area 24 above the cooking cavity 22 can affect the temperature of the electronics area 24 and the various electronic components 64 disposed therein. Heat from the cooking cavity 22 can transfer or otherwise be directed from the cooking cavity 22 to the electronics area 24. Accordingly, ventilation is utilized for cooling the electronics area 24, as well as other locations in the cooking appliance 10. As described further herein, the controller 40 may actively control the cooling fan 28 and, consequently, the ventilation to reduce or prevent additional heat from being drawn into the electronics area 24.

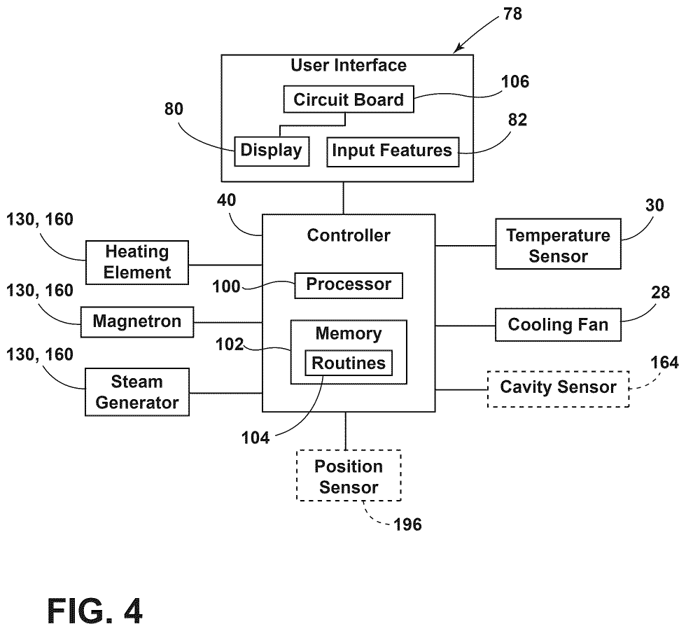

Referring still to FIG. 3, as well as FIG. 4, the electronics area 24 is configured to house a variety of electronic components 64. The electronic components 64 may include an appliance control unit (ACU) 40 or control board 40, which may be referred to herein as the controller 40. The controller 40 may include a processor 100 or microprocessor 100, a memory 102, and other control circuitry. Instructions or routines 104 (i.e., software or control logic) are stored within the memory 102 and executable by the processor 100. The controller 40 is generally communicatively coupled with the electronic components 64 of the cooking appliance 10. The controller 40 is configured to receive inputs and generate/send outputs, including routines 104 related to controlling the various electronic components 64 and performing the processes and methods described herein. For example, the controller 40 generally includes a delayed cooling routine 104 for the active control of the ventilation during a cooling state of the appliance 10 as described herein. In addition to the controller 40, a user-interface (UI) circuit board 106 may also be disposed within the electronics area 24 and can be communicatively coupled with the controller 40.

The temperature sensor 30 is also generally positioned in the electronics area 24. In certain aspects, the temperature sensor 30 is on, or integrated with, the controller 40 (i.e., the control board). The temperature sensor 30 may be configured as a thermistor. The temperature sensor 30 is configured to sense the temperature within the electronics area 24, including the air temperature and/or temperatures of components in the electronics area 24, such as the controller 40 to which the sensor 30 is coupled. The temperature sensor 30 is configured to sense the temperature and communicate the sensed temperature 42 to the controller 40.

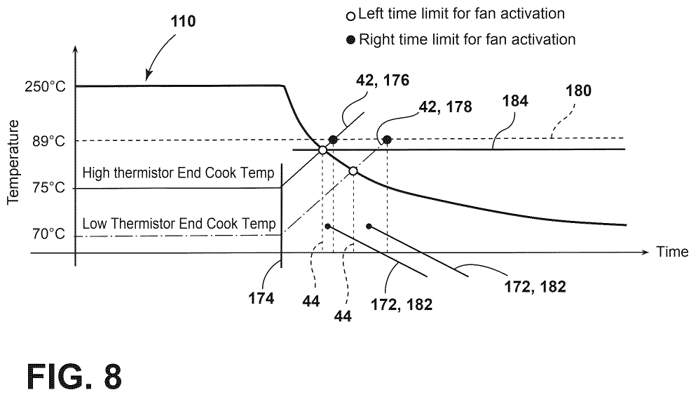

The controller 40 may be configured to determine or estimate a temperature within the cooking cavity 22 (also referred to as a cavity temperature 110 or center cavity temperature 110). In this regard, the temperature sensor 30 may be calibrated to the cooking cavity 22, and the sensed temperature 42 output by the temperature sensor 30 may be indicative of or correlated to the cavity temperature 110 (see FIG. 8). Calibration or other correlation information may be predefined and/or may be stored in the controller 40. The sensed temperature 42 may indicate the center cavity temperature 110, which can be used for controlling the cooling fan 28, as described herein.

Referring still to FIGS. 3 and 4, the cooling fan 28, along with an associated fan motor 112, is also disposed within the electronics area 24 above the cooking cavity 22. In certain aspects, a single cooling fan 28 can be utilized to provide ventilation for the entire cooking appliance 10. In such examples, the cooling fan 28 is utilized to direct air along a ventilation path that extends through the door 32, through the electronics area 24, through a duct 114, and through one or more internal passages 116 between the external enclosure 12 and the internal housing 20 before being expelled from the cooking appliance 10. Multiple fans 28 may also be utilized without departing from the teachings herein.

The electronics area 24 may include multiple dividers 118-122 for separating the area 24 and guiding the airflow along the ventilation path. In the illustrated example, the first divider 118 extends laterally and is arranged behind the controller 40. The cooling fan 28 is illustrated to a side of the space between the first divider 118 and the UI circuit board 106. The cooling fan 28 is configured to draw air into the electronics area 24 via the inlets 16, 18 and across the controller 40, the UI circuit board 106, and other components 64. The first divider 118 may assist with directing the air more directly across the electronic components 64 and toward the cooling fan 28.

The second divider 120 extends in the fore-aft direction from the first divider 118 proximate to the cooling fan 28, and the third divider 122 extends between the second divider 120 and the external enclosure 12. The second and third dividers 120, 122 may form a space for cooking components 130, such as a microwave power supply 132, also referred to as a magnetron, for generating microwaves in the cooking cavity 22. The cooling fan 28 may be configured to direct the air through the space for the microwave power supply 132 and into the duct 114. The duct 114, or multiple ducts 114, can be used to direct the air elsewhere in the cooking appliance 10. For example, the air can be directed by the cooling fan 28 through the duct 114 and then through internal passages 116 between the external enclosure 12, the internal housing 20, and/or the internal panel(s) 88. Generally, the internal passages 116 direct the air along a back of the cooking appliance 10 and then along a bottom of the cooking appliance 10 to be expelled from the external enclosure 12. The air can be expelled via outlets 134 along a bottom portion of the external enclosure 12, proximate the back, proximate the front, or via the door 32.

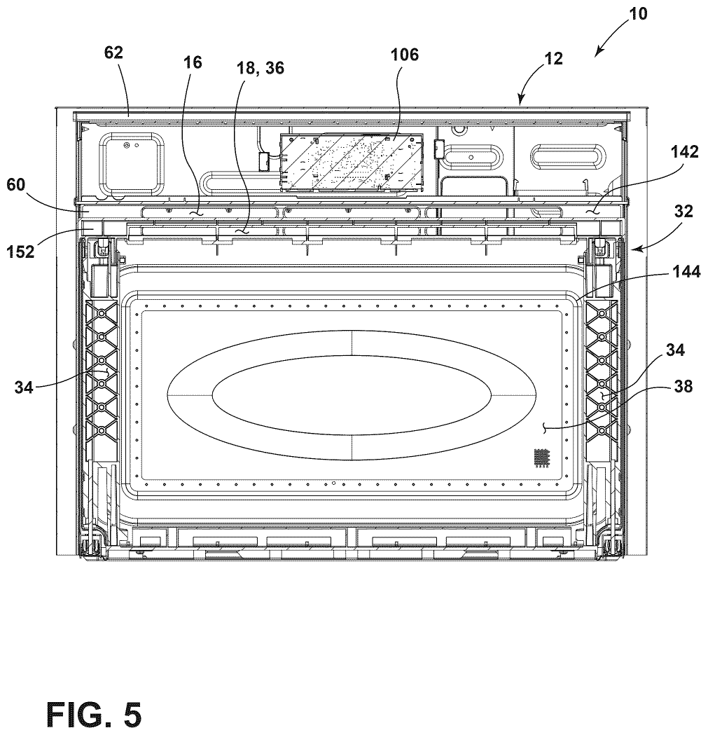

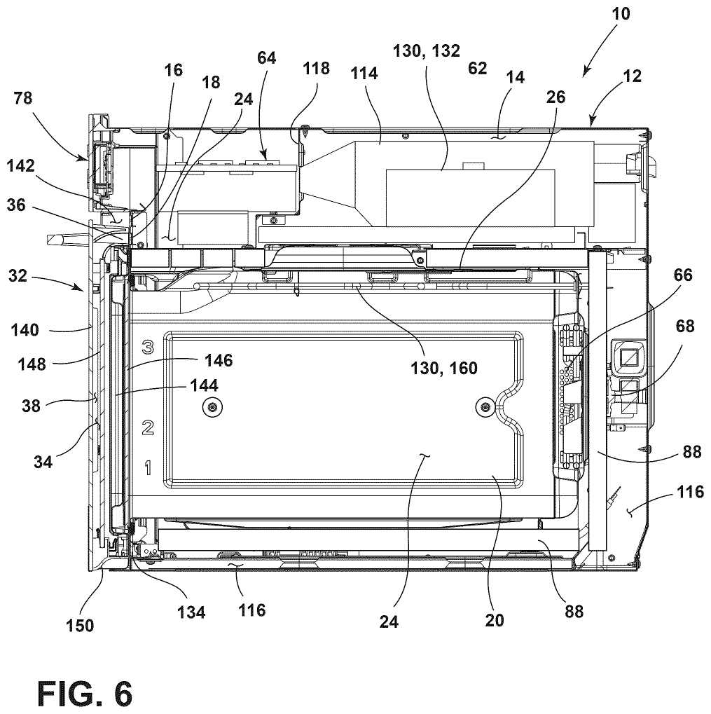

Referring to FIGS. 5 and 6, the cooling fan 28 is configured to draw air into the electronics area 24 through the upper and lower inlets 16, 18. In various aspects, the air drawn through the upper inlets 16 is drawn directly from the surrounding environment, while the air drawn through the lower inlets 18 is drawn through the door 32 from the surrounding environment. When the door 32 is in the closed position, an outer surface 140 of the door 32 may be aligned or coplanar with the user interface 78. An airflow gap 142 may be defined between a top of the door 32 and the user interface 78, where the airflow gap 142 provides fluid communication between the external, surrounding environment and the upper inlets 16. Accordingly, the cooling fan 28 is configured to draw “fresh” air from the surrounding environment through the airflow gap 142, through the upper inlets 16, and into the electronics area 24.

Additionally, when the door 32 is in the closed position, the cooling fan 28 is configured to direct air through the door 32. In this regard, the door 32 may form a portion of the cooling or ventilation airflow path when the door 32 is in the closed position. The door 32 generally includes an inner frame 144, which may assist in coupling various components of the door 32 together. The inner frame 144 may also assist with spacing between an inner surface 146 of the door 32 enclosing the cooking cavity 22 and the door passage 38 to assist with heat dissipation to the door passage 38 and, consequently, air drawn through the door passage 38. The door 32 also includes the outer surface 140 or outer panel 140 and an interior panel 148, which form the door passage 38 therebetween. A lower coupling feature 150 may couple the outer panel and 140 the interior panel 148 at a bottom of the door 32. The lower coupling feature 150 may also form the door inlets 34 along a width of the door 32.

The door inlets 34 are in fluid communication with the door outlets 36 with the door passage 38 at an outer side of the door 32 to reduce heat captured in the airflow through the door 32. The cooling fan 28 is configured to draw air from the surrounding environment into the door 32 through the door inlets 34. The activation of the cooling fan 28 generally generates a reduced or negative pressure, causing the air to be drawn into the cooking appliance 10. The air is configured to flow through the door passage 38 toward the top of the door 32. A guide feature 152 is included at the top of the door 32, which may form a portion of the airflow gap 142 and a portion of the door passage 38. The guide feature 152 may define the door outlets 36 proximate to the top of the door 32.

The door outlets 36 are arranged on an inner side of the door 32 to align or mate with the lower inlets 18 of the front panel 60. The door outlets 36 are generally arranged in a lateral configuration and have a shape and size that correspond with the shape and size of the lower inlets 18. In various aspects, the guide feature 152 fluidly couples the door passage 38 (e.g., a vertical portion of the door passage 38) with the lower inlets 16, 18. Accordingly, the air is drawn through the door passage 38, through the door outlets 36, and through the lower inlets 18 into the electronics area 24. The cooling fan 28 is configured to concurrently draw air through the upper inlets 16 and lower inlets 18 when activated.

Referring to FIG. 6, as well as FIG. 7, when the door 32 is in the closed position, air is drawn through the airflow gap 142 and the upper inlets 16, forming a first airflow branch, and through the door 32 and the lower inlets 18, forming a second airflow branch. The airflow branches converge in the electronics area 24. When the door 32 is moved to the opened position, the ventilation airflow path (e.g., a fluid path) is disrupted or changed as the second airflow branch through the door 32 is no longer utilized or is significantly affected. In other words, the ventilation path is generally disrupted between the door outlets 36 and the lower inlets 16, 18. The door 32 is moved away from the front panel 60 and the door outlets 36 are spaced from the lower inlets 16, 18 such that there is generally no longer direct fluid communication between the door outlets 36 and the electronics area 24 or the door 32 is generally free of air directed by the cooling fan 28. However, with the door in the opened position, the cooling fan 28 is configured to draw air through both the upper and lower inlets 16, 18 from a space between the open door 32 and the external enclosure 12.

In conventional arrangements, cooling fans in electronics spaces arranged above the cooking chamber typically capture and draw heated air into the electronics space. In this regard, the door is opened, allowing the heated air from the cooking chamber to begin to escape the cooking chamber. When fans are active, the fans draw air from the cooking chamber too when the cooking chamber is exposed/opened by the door. The fans then capture the heated air and direct the heated air into the electronics space, further heating the electronics, which can impact the function and longevity of the electronics. Certain conventional devices may also implement a specific mode for when the door is open due to a rapid increase in temperature of the electronics and/or the electronics being over-temperature. Conventional cooking devices generally cannot sustain the active fan with the door open.

Referring again to FIGS. 3-7, in the cooking appliance 10 disclosed herein, the controller 40 includes one or more routines 104 for pausing or delaying the activation of the cooling fan 28 based on a position of the door 32 and/or an end cooking time (indicative of the door 32 to be opened). This pause or delay reduces the heated cooking cavity 22 air that is drawn into the electronics area 24, reducing the impact of heat on the electronic components 64. In other words, the cooking appliance 10 described herein may actively control the cooling fan 28 based on the sensed temperature 42 to reduce the amount of heated air the cooling fan 28 directs from the cooking cavity 22 and into the electronics area 24. The cooling fan 28 may also be controlled based on the cooking process being performed.

The cooking appliance 10 may have a variety of configurations such as a conventional oven, a convection oven, a steam oven, a microwave oven, a multifunction cooking appliance, a microwave combination (“combi”) appliance, or a combination of one or more types of cooking appliance. For example, the cooking appliance 10 may provide multiple cooking processes, including one or more of steam, conventional heating, convection, broiling, microwave, grilling, air frying, etc. In the illustrated configuration, the cooking appliance 10 includes a heating element 160 (such as a radiant heating element), the circulation/convection fan 68, a steam generator 162, and the microwave power supply 132. In such examples, the cooking appliance 10 can use radiant heating, airflow, steam, and/or microwaves for heating and/or cooking the food item in the cooking cavity 22.

The type of cooking process being performed can affect the control of the cooling fan 28. For example, the cooling fan 28 operations can be paused or delayed with the delayed cooling routine 104 based on the cavity temperature 110 and/or a desired temperature margin used for the cooking process. The cavity temperature 110 can be estimated using the temperature sensor 30, may be sensed via a cavity sensor 164, and/or may be programmed or stored based on a selected cooking process. For example, the delayed cooling routine 104 may be activated or implemented by the controller 40 when the cavity temperature 110 is at or exceeds a predefined cavity temperature. For example, above 100° C., above 200° C., etc. This predefined cavity temperature is sufficiently high that the heated air from the cooking cavity 22 may negatively impact the electronic components 64 should the heated air be directed through the electronics area 24.

In comparison, the delayed cooling routine 104 may not be implemented when the cavity temperature 110 does not reach the predefined cavity temperature. For example, when using the microwave power supply 132, the cavity temperature 110 may not reach the predefined temperature. In such examples, the delayed cooling routine 104 may not be implemented and, therefore, the operation of the cooling fan 28 may not be changed or affected. In this way, the controller 40 can control and delay/pause the cooling fan 28 under certain cooking conditions, which may not be implemented for other processes.

The controller 40 of the cooking appliance 10 may actively and/or dynamically control the cooling fan 28 based on the position of the door 32 and/or the end of the cooking process so as to reduce or prevent heated air from the cooking cavity 22 from being drawn into the electronics area 24 under select cooking conditions. The reduction of the heated air from the heated cooking cavity 22 being drawn into the electronics area 24 may reduce failure or damage of the electronic components 64 in the electronics area 24. This may also increase longevity and accuracy in the electronic components 64 by retaining the electronic components 64 at cooler temperatures.

Referring still to FIG. 3, as well as FIGS. 8-10, the controller 40 may store an upper temperature value 180 for the electronic components 64 and/or the electronics area 24. This upper temperature value 180 may be an upper limit for the temperature that the electronic components 64 can operate and withstand before the temperature begins to significantly affect the electronic components 64 or functions thereof. In other words, this upper temperature value 180 may be a limit or threshold for the electronic components 64. In the illustrated example, the upper temperature value 180 is 89° C. The control of the cooling fan 28 may be utilized to retain the electronic components 64 below the upper temperature limit 180. The upper temperature value 180 may be between 80° C. and 100° C. but may be any value where the electronic components 64 or functions of the electronic components 64 begin to be affected, which may differ based on the electronic components 64 included in the electronics area 24 and/or the configuration of the cooking appliance 10.

A fan activation time 172 may be based on the upper temperature value 180 and/or the center cavity temperature 110, which may be estimated based on the correlation between the sensed temperature 42 and the cavity temperature 110. For example, the sensed temperature 42 in the electronics area 24 and/or the sensed temperature 42 of the electronic component 64 to which the temperature sensor 30 is coupled, may correlate to a specific center cavity temperature 110 or range, allowing the controller 40 to utilize the sensed temperature 42 for controlling the cooling fan 28. In this way, the controller 40 is configured to actively control the cooling fan 28 based on a sensed temperature 42 relative to a predefined temperature with the door 32 in the opened position.

Referring to FIG. 8, relationships between the center cavity temperature 110, the upper temperature value 180, the sensed temperature 42, including upper sensed temperature 176 and lower sensed temperature 178, and fan activation times 172 are illustrated. In the illustrated example, the center cavity temperature 110 is maintained at a set cooking temperature, which is 250° C. in this example, until the door 32 is opened at time 174. When the door 32 is opened, the center cavity temperature 110 declines. The decline may be exponential for an initial greater decline and then a lesser subsequent decline.

The graph includes two sensed temperatures 42, which are illustrated at about 75° C. and about 70° C., respectively. The first or higher sensed temperature 176 may be representative of electronic components 64 reaching a higher sensed temperature 176 at the end of the cooking cycle (i.e., the cooking process until the door 32 is opened). The second or lower sensed temperature 178 may be representative of electronic components 64 reaching a lower sensed temperature 178 at the end of the cycle. The difference in sensed temperature 42 may be related to ambient temperature, fan speed of the cooling fan 28 during the cooking process, duration of the cooking process, age of the electronic components 64, door opening events during the cooking process, etc.

As illustrated, when the door 32 is opened, the center cavity temperature 110 decreases while the sensed temperatures 42 increase. The higher sensed temperature 176 intersects with the center cavity temperature 110 more quickly compared to the lower sensed temperature 178, which intersects with the center cavity temperature 110 at a later time and a lower temperature. The intersection points may represent the start of windows 182 for a latest time range for the fan activation time 172 to retain the sensed temperatures 42 below the upper temperature limit 180. This results in a shorter activation window 182 between the intersection point and the upper temperature limit 180 for the higher sensed temperature 176 and a longer activation window 182 between the intersection point and the upper temperature limit 180 for the lower sensed temperature 178.

The controller 40 may also store a temperature margin value 184, which is below the upper temperature value 180. The temperature margin value 184 may be a temperature that represents a latest time for activating the cooling fan 28 before the electronic components 64 reach the upper temperature limit 180. Activating the fan at the temperature margin value 184 may assist with reducing the temperature of the electronic components 64 for operation and functionality and may retain the temperature below the upper threshold value 180. Typically, the cooling fan 28 is activated prior to the sensed temperature 42 reaching the margin value 184 as the activation times 172 actively based on the sensed temperature 42 generally retain the sensed temperature 42 below the upper limit 180. This temperature margin value 184 may be predefined based on the electronic components 64 (e.g., related to the upper limit 180), the cooking appliance 10, the cooking process, etc.

As illustrated in FIG. 8, the start of the activation window 180 for the cooling fan 28 is closer to the temperature margin value 184 for the higher sensed temperature 176 than the lower sensed temperature 178. The margin for implementing the cooling process is shorter when there is a higher sensed temperature 176, and the margin for implementing the cooling process is larger when the sensed temperature 178 is lower. This can result in the activation of the cooling fan 28 sooner for higher sensed temperatures 176 compared to lower sensed temperatures 178 for retaining the electronic components 64 below the upper threshold value 180. Generally, the cooling fan 28 is activated up to a maximum speed to increase the effect of the cooling process. As the center cavity temperature 110 decreases, activating the cooling fan 28 at the maximum speed may not draw in a significant amount of heated air due to the delay in activation.

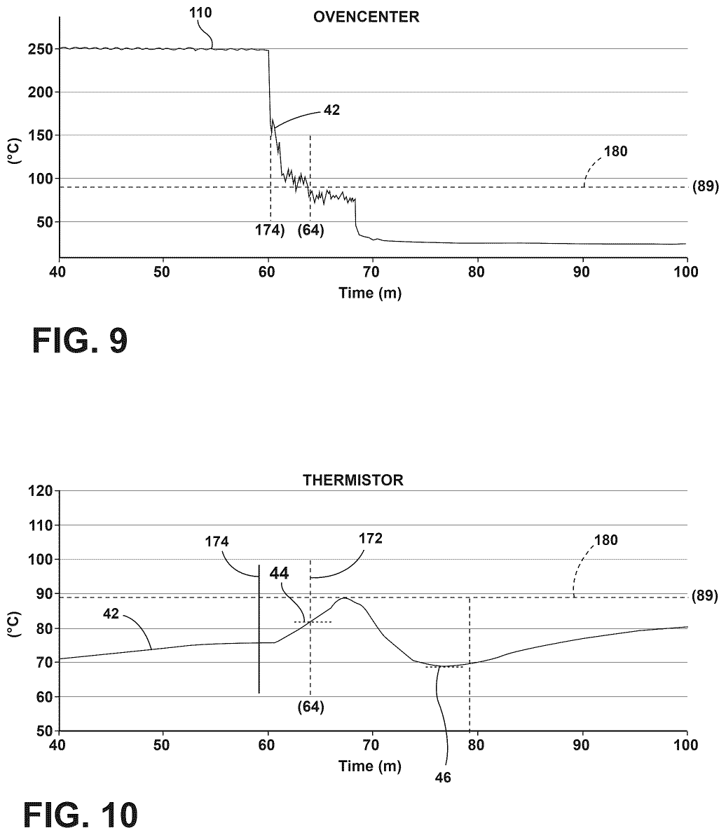

Referring to FIGS. 9 and 10, the sensed temperature 42 may be calibrated with the center cavity temperature 110 to determine the activation time 172. Tests were conducted using a cooking temperature of 250° C., the upper temperature value 180 (e.g., the ACU thermal limit) of 89° C., the delayed cooling routine 104, and the cooling fan 28. As represented by line 42, a test was conducted using a maximum fan speed for the cooling fan 28, and additional testing test was conducted using a lesser fan speed (i.e., less than the maximum speed). The graph in FIG. 9 illustrates the center cavity temperature 110 over time, and the graph in FIG. 10 illustrates the sensed temperature 42 over time. The testing was conducted with the door 32 remaining open after the opening point 174.

The center cavity temperature 110 was started at 250° C., with a cooking process ending (i.e., the cooking components 130 deactivated) and the door 32 being moved to the opened position at 60 minutes. Upon the door 32 opening, the center cavity temperature 110 declined, with some variation, within 10 minutes of the door 32 being opened. Based on the test data, the center cavity temperature 110 fell below and remained below the upper temperature value 180 of 89° C. at minute 64.

The sensed temperature 42 increased slightly during the cooking process as the center cavity temperature 110 remained at 250° C. before the door 32 was opened. When the door 32 was opened at 60 minutes, the cooling fan 28 was deactivated/remained inactive, and the sensed temperature 42 began to increase more quickly.

As the center cavity temperature 110 fell below the upper threshold value 180, the sensed temperature 42 reached the predefined temperature for activating the cooling fan 28. Accordingly, at 64 minutes into the test, the cooling fan 28 was activated with the door 32 open. As illustrated in FIG. 10, after activation of the cooling fan 28, the sensed temperature 42 continued to increase and then the sensed temperature 42 began to decline. With the delay in the activation of the cooling fan 28, the sensed temperatures 42 did not exceed the upper temperature limit 180 (e.g., 89° C. in the illustrated example). Accordingly, by delaying activation of the cooling fan 28 based on the center cavity temperature 110 when the door 32 is opened, the sensed temperature 42 for the electronic components 64 may not exceed the upper temperature limit 180 for the electronic components 64. This may be advantageous for configurations with the cooling fan 28 above the cooking cavity 22 to reduce the heat drawn into the electronics area 24 from the cooking cavity 22.

The calibration based on the center cavity temperature 110 or the correlation between the center cavity temperature 110 and the sensed temperature 42 may be based on one or more factors. For example, the relationship may be inverse, such that the increase in sensed temperature 42 may indicate a predefined cooling in the center cavity temperature 110. In a non-limiting example, a predefined increase in sensed temperature 42 or an increase to the predefined temperature 44 may indicate that the center cavity temperature 110 has cooled to or below the upper limit 180, such that any air drawn into the electronics area 24 would be at or below the upper temperature 180.

Additionally or alternatively, the sensed temperature 42 may indicate the center cavity temperature 110 has cooled by a predefined temperature. In such examples, the cooler center cavity temperature 110 along with a predefined airflow rate of the cooling fan 28 may be related to a time for the electronic components 64 to begin to cool. In this way, the temperatures 42, 110, airflow rate, and time may be utilized to determine the activation time 174. Any calibration or correlation may be used for the sensed temperature 42 to retain the sensed temperature 42 below the upper limit 180 without departing from the teachings herein.

Referring to FIGS. 1-10, for each cooking appliance 10 or type of cooking process, the activation time for the cooling fan 28 may differ based on the center cavity temperature 110, the sensed temperature(s) 42, and the correlation therebetween. Accordingly, the controller 40 may store predefined values, including the upper temperature limit 180, as well as activation times 172 for the cooling fan 28 based on center cavity temperatures 110, sensed temperature 42, and correlation data. In this way, the activation time for the cooling fan 28 is calibrated to the center cavity temperature 110 and indicative of the cavity temperature 110. In other words, the cooling fan 28 may be activated when a predetermined threshold 44 is reached, where the predetermined threshold 44 is a correlation between the sensed temperature 42 (indicative of the cavity temperature 110) and the electronic component 64 in the electronics area 24. The sensed temperature 42 may be utilized to estimate the center cavity temperature 110. It is also contemplated that the controller 40 may utilize the sensed temperature 42 from the cavity sensor 164 without departing from the teachings herein.

The cooling fan 28 may or may not be active when the door 32 is closed and the cooking process is in progress. When the door 32 is opened, the controller 40 may be configured to deactivate the cooling fan 28 if the cooling fan 28 is active or delay the activation of the cooling fan 28 (i.e., retain the cooling fan 28 in the inactive state). The controller 40 may determine that door 32 is opened from a position sensor 196, from the end of the cooking time or selected cooking process (as stored in the memory 102 or provided by routines 104) indicating the door 32 is to be opened to remove the food item, and/or a significant increase or increase over time in the sensed temperature 42.

Once the predefined threshold 44 is reached, the controller 40 is configured to activate the cooling fan 28 in response to the sensed temperature 42 and retain the cooling fan 28 in the active state for cooling the electronic components 64 with the door 32 opened. Typically, the cooling fan 28 is activated to the maximum speed during the delayed cooling routine 104. If the door 32 is closed when the delayed cooling routine 104 is implemented, the delayed cooling routine 104 may be deactivated as the ventilation/cooling through the door 32 may again be available. Accordingly, the delayed cooling routine 104 may remain in effect when the door 32 is in the opened position, which is when the cooling fan 28 may draw the heated cavity air into the electronics area 24. The delayed cooling routine 104 may be utilized in circumstances where the door 32 is opened and remains open for at least a predefined period of time, such as when the cooking process has ended or when a user is checking a temperature of the food item and then closes the door 32 to continue the cooking process.

When the door 32 is opened, the controller 40 is configured to retain the cooling fan 28 in the inactive state until the sensed temperature 42 reaches the deactivation temperature 46. With the fan 28 remaining active, the sensed temperature 42 generally declines until the sensed temperature 42 remains below the deactivation temperature 46. When the sensed temperature 42 reaches or falls below the deactivation temperature 46, the cooling fan 28 may be deactivated. The deactivation temperature 46 may be any temperature at which the electronic components 64 may no longer actively be cooled without significant effect on the electronic components 64 (e.g., within a lower temperature margin). The deactivation temperature 46 may be the same or different than the activation temperature 44. In certain aspects, the deactivation temperature 46 is lower than the activation temperature 44.

In sum, with the delayed cooling routine 104, when the door 32 is opened, the cooling fan 28 is inactive until the temperature sensor 30 senses the first predefined temperature 44 (calibrated to the center cavity temperature 110). The cooling fan 28 is then activated and remains in the active state until the sensed temperature 42 reaches or falls below the second predefined temperature 46, where the cooling fan 28 is then deactivated. With the delayed cooling routine 104, the cooking appliance 10 can cool the electronic components 64 with the opened door 32 for an indefinite amount of time. The controller 40 may continue to monitor the sensed temperature 42 and actively activate and deactivate the cooling fan 28 based on the sensed temperature 42.

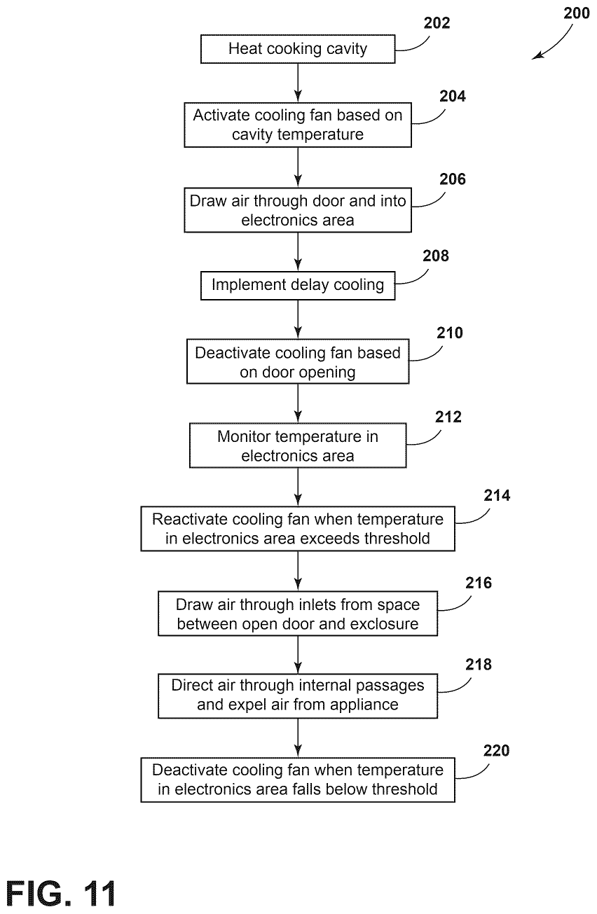

With reference to FIG. 11, as well as FIGS. 1-10, a method 200 of controlling ventilation of the cooking appliance 10 includes starting a cooking process (step 202). During the cooking process, the cooking cavity 22 may be heated using one or more cooking components 130. The controller 40 may be configured to activate the cooling fan 28 based on the cavity temperature 110 and/or cooking process (step 204). The cooling fan 28 is configured to draw air into the electronics area 24 for cooling the electronic components 64 (step 206). When the door 32 is in the closed position, the cooling fan 28 is configured to draw from the external environment, through the airflow gap 142, and through the upper inlets 16, as well as from the external environment, through the door 32, and through the lower inlets 18.

When the cooking cavity 22 reaches the predefined cavity temperature, the controller 40 may initiate or activate the delayed cooling routine 104 (step 208). When the door 32 is moved to the opened position and/or at the end of the cooking cycle, the controller 40 is configured to deactivate the fan 28 or retain the cooling fan 28 in the inactive state with the delayed cooling routine 104 (step 210). The controller 40 may determine whether a timer is complete or a selected cooking process is complete, indicating that door 32 is to be opened shortly. The controller 40 may monitor sensed information from the position sensor 196 to determine the position of the door 32.

The controller 40 is configured to monitor the sensed temperature 42 from the temperature sensor 30 in the electronics area 24 (step 212). The sensed temperature 42 may be calibrated to or indicative of the center cavity temperature 110. The controller 40 may compare the sensed temperature 42 to stored values.

The controller 40 is configured to activate the cooling fan 28 when the sensed temperature 42 reaches or exceeds the first predefined temperature 44 (step 214). The first predefined temperature 44 is generally based on the correlation between the center cavity temperature 110 and the temperature of the electronic components 64 (e.g., the sensed temperature 42). In certain aspects, the first predefined temperature 44 may be when the sensed temperature 42 indicates that the center cavity temperature 110 has fallen below the upper temperature limit 180. The controller 40 is configured to activate the fan 28 before or within a window 182 based on the sensed temperature 42 and the temperature margin value 184 for retaining the sensed temperature 42 below the upper temperature value 180. The cooling fan 28 is generally activated at the maximum speed.

With the door 32 remaining in the opened position, the controller 40 is configured to continue to monitor the sensed temperature 42 and draw air into the electronics area 24 (step 216). The fan 28 is configured to draw air through the upper and lower inlets 16, 18 and, with the decrease in temperature 110 of the cooking cavity 22, the air captured by the cooling fan 28 may not be heated to an extent where the heat affects the electronic components 64. The air can be directed by the cooling fan 28 through the cooking appliance 10 and then expelled from the appliance 10 (step 218). When the sensed temperature 42 reaches or falls below the second predefined temperature 44, the controller 40 is configured to deactivate the cooling fan 28 (step 220). If the door 32 is closed at any point during this cooling process, the controller 40 may deactivate the delayed cooling routine 104 until the door 32 is again opened. Accordingly, the controller 40 may implement and deactivate the routine 104 repeatedly based on the cooking time/process and/or the position of the door 32. Further, the fan 28 may be repeatedly activated and deactivated based on the sensed information to provide the open door 32 cooling process for an indefinite period of time. The steps 202-216 of the method 200 may be performed in any order, performed sequentially, performed concurrently, and/or have steps omitted or repeated without departing from the teachings herein.

Use of the present system may provide a variety of advantages. For example, the cooking appliance 10 provides active and dynamic control of the cooling fan 28 based on the temperature sensed by the temperature sensor 30 in the electronics area 24. In this regard, the cooking appliance 10 may have an open door 32 cooling state. Further, the ventilation/cooling control may be accomplished via the correlation between the temperature of the electronics (e.g., the sensed temperature 42) and the center cavity temperature 110. Moreover, the controller 40 is configured to deactivate the cooling fan 28 to reduce heated air from the heated cooking cavity 22 being drawn into the electronics area 24 as the door 32 is opened, delaying the cooling down fan state for the appliance 10. The heated air could cause the electronic components 64 to be at a higher temperature even with the active airflow through the electronics area 24, so reducing the heat captured within the airflow is advantageous for the function and longevity of the electronic components 64. Additionally, the control of the cooling fan 28 can be based on sensed temperature 42 to reduce or prevent the temperature of the electronic components 64 from exceeding an upper limit.

Also, the controller 40 is configured to continually monitor the temperature sensed 42 by the temperature sensor 30 and activate the cooling fan 28 at the activation time 172, which retains the sensed temperature 42 below the upper temperature threshold. Additionally, the controller 40 is configured to control the cooling fan 28 in a different manner when the door 32 is in the opened position compared to the closed position, as well as with different cooking processes. Further, the delayed cooling routine 104 can assist with more quickly and efficiently reducing the temperature of the electronic components 64 when the door 32 is open. In this regard, the cooking appliance 10 is configured to cool the electronics area 24 with the open door 32 for an indefinite period of time due to the active control of the cooling fan 28. Further, the cooking appliance 10 can include a single cooling fan 28 for cooling the cooking appliance 10, which can be actively controlled to reduce the capture of air from the cooking cavity 22 with an open door 32. Additional benefits or advantages may be realized and/or achieved.

The device disclosed herein is further summarized in the following paragraphs and is further characterized by combinations of any and all various aspects described therein.

According to another aspect of the present disclosure, a cooking appliance includes an external enclosure defining an interior. The external enclosure defines at least one inlet at an upper portion thereof. An internal housing defines a cooking cavity. The internal housing is disposed within the interior. An electronics area is defined between a top of the internal housing and the external enclosure. A cooling fan is disposed in the electronics area and is in fluid communication with the at least one inlet. A temperature sensor is disposed within the electronics area. A door is operably coupled with the external enclosure for enclosing the cooking cavity. The door defines a door inlet that is fluidly coupled with a door outlet via a door passage. The door outlet is in fluid communication with the at least one inlet when the door is in a closed position. A controller is communicatively coupled with the cooling fan. The controller is configured to activate the cooling fan to draw air through the door passage and into the electronics area when the door is in the closed position, deactivate the cooling fan in response to the door moving to an opened position, and reactivate the cooling fan in response to a sensed temperature sensed by the temperature sensor exceeding a predefined temperature.

According to another aspect, at least one inlet includes a first inlet and a second inlet. The first inlet is in fluid communication with a door passage when a door is in a closed position. The second inlet is defined above a top of the door.

According to yet another aspect, a controller is configured to implement a delayed cooling routine in response to a cavity temperature exceeding a predefined cavity temperature for a cooking process.

According to yet another aspect, a heating element is configured to heat a cooking cavity. A magnetron is configured to generate microwaves within the cooking cavity.

According to yet another aspect, a cooling fan is configured to draw air from a space between an inner surface of a door and a front panel of an external enclosure when the door is in an opened position. A fluid path is between the door passage and at least one inlet is disrupted when the door is in the opened position.

According to yet another aspect, a controller is configured to reactivate a cooling fan at a maximum speed.

According to yet another aspect, a controller is configured to deactivate a cooling fan in response to a sensed temperature falling below a second predefined temperature.

According to yet another aspect, a controller is configured to actively control a cooling fan in response to a sensed temperature. The sensed temperature is correlated to a center cavity temperature of a cooking cavity.

According to another aspect, According to another aspect of the present disclosure, a combination cooking appliance includes an external enclosure defining a first inlet and a second inlet. An internal housing defines a cooking cavity. An electronics area is defined between the external enclosure and the internal housing proximate to the first and second inlets. At least one cooking component is operably coupled with the cooking cavity. A door is operably coupled with the external enclosure. The door defines a door inlet and a door outlet. The door outlet is in fluid communication with the first inlet. A cooling fan is disposed within the electronics area. A temperature sensor disposed within the electronics area. A controller is communicatively coupled with the cooling fan. The controller is configured to at least one of deactivate the cooling fan and retain the cooling fan in an inactive state in response to the door moving to an opened position, receive a sensed temperature from the temperature sensor, activate the cooling fan when the sensed temperature exceeds a first predefined temperature with the door in the opened position, and deactivate the cooling fan when the sensed temperature reaches a second predefined temperature.

According to yet another aspect, a controller is configured to reactivate a cooling fan when a sensed temperature from the temperature sensor exceeds a first predefined temperature.

According to yet another aspect, a controller is configured to activate a cooling fan to form a ventilation path from a surrounding environment through a second inlet and from a door passage through a first inlet when a door is in a closed position.

According to another aspect, a cooling fan is configured to draw air directly from a surrounding environment and through a first inlet when a door is in an opened position.

According to yet another aspect, a controller is configured to deactivate a cooling fan when a sensed temperature falls below a second predefined temperature.

According to yet another aspect, an electronics area is defined between a top of an internal housing and a top panel of an external enclosure.

According to yet another aspect, a cooling fan is configured to draw air from an external environment and through a first inlet when a door is in an opened position.

According to yet another aspect, a controller is configured to actively control a cooling fan based on a sensed temperature with a door in an opened position.

According to yet another aspect, a predefined temperature is based on a correlation between a cooking cavity and a sensed temperature.

According yet to another aspect, a method of controlling ventilation of a cooking appliance includes heating a cooking cavity; activating a cooling fan in response to a temperature of the cooking cavity exceeding a predefined cavity temperature; drawing air through a door passage, through an inlet, and into an electronics area with the cooling fan when a door is in a closed position; deactivating the cooling fan in response to the door moving to an opened position; and reactivating the cooling fan in response to a sensed temperature from a temperature sensor within the electronics area exceeding a predefined temperature with the door in the opened position.

According to yet another aspect, a method includes deactivating a cooling fan when a sensed temperature falls below a second predefined temperature.

According to yet another aspect, a method includes drawing air through an inlet from a space between an inner surface of a door and a front panel of an external enclosure when the door is in an opened position. A door passage is free of the air directed by a cooling fan when in the opened position.

According to yet another aspect, a method includes directing air through an electronics area and through an internal passage between an external enclosure and an internal housing to expel the air from the external enclosure via an outlet at a bottom portion of the external enclosure.

According to yet another aspect, a step of reactivating a cooling fan in response to a sensed temperature includes reactivating the cooling fan at a maximum speed.

It will be understood by one having ordinary skill in the art that construction of the described disclosure and other components is not limited to any specific material. Other exemplary embodiments of the disclosure disclosed herein may be formed from a wide variety of materials, unless described otherwise herein.

For purposes of this disclosure, the term “coupled” (in all of its forms, couple, coupling, coupled, etc.) generally means the joining of two components (electrical or mechanical) directly or indirectly to one another. Such joining may be stationary in nature or movable in nature. Such joining may be achieved with the two components (electrical or mechanical) and any additional intermediate members being integrally formed as a single unitary body with one another or with the two components. Such joining may be permanent in nature or may be removable or releasable in nature unless otherwise stated.

It is also important to note that the construction and arrangement of the elements of the disclosure as shown in the exemplary embodiments is illustrative only. Although only a few embodiments of the present innovations have been described in detail in this disclosure, those skilled in the art who review this disclosure will readily appreciate that many modifications are possible (e.g., variations in sizes, dimensions, structures, shapes, and proportions of the various elements, values of parameters, mounting arrangements, use of materials, colors, orientations, etc.) without materially departing from the novel teachings and advantages of the subject matter recited. For example, elements shown as integrally formed may be constructed of multiple parts or elements shown as multiple parts may be integrally formed, the operation of the interfaces may be reversed or otherwise varied, the length or width of the structures and/or members or connector or other elements of the system may be varied, the nature or number of adjustment positions provided between the elements may be varied. It should be noted that the elements and/or assemblies of the system may be constructed from any of a wide variety of materials that provide sufficient strength or durability, in any of a wide variety of colors, textures, and combinations. Accordingly, all such modifications are intended to be included within the scope of the present innovations. Other substitutions, modifications, changes, and omissions may be made in the design, operating conditions, and arrangement of the desired and other exemplary embodiments without departing from the spirit of the present innovations.

It will be understood that any described processes or steps within described processes may be combined with other disclosed processes or steps to form structures within the scope of the present disclosure. The exemplary structures and processes disclosed herein are for illustrative purposes and are not to be construed as limiting.

1. A cooking appliance, comprising:
an external enclosure defining an interior, wherein the external enclosure defines at least one inlet at an upper portion thereof;
an internal housing defining a cooking cavity, wherein the internal housing is disposed within the interior, and wherein an electronics area is defined between a top of the internal housing and the external enclosure;
a cooling fan disposed in the electronics area and in fluid communication with the at least one inlet;
a temperature sensor disposed within the electronics area;
a door operably coupled with the external enclosure for enclosing the cooking cavity, wherein the door defines a door inlet fluidly coupled with a door outlet via a door passage, the door outlet in fluid communication with the at least one inlet when the door is in a closed position; and
a controller communicatively coupled with the cooling fan, wherein the controller is configured to:
activate the cooling fan to draw air through the door passage and into the electronics area when the door is in the closed position;
deactivate the cooling fan; and
reactivate the cooling fan in response to a sensed temperature sensed by the temperature sensor exceeding a predefined temperature.

2. The cooking appliance of claim 1, wherein the at least one inlet includes a first inlet and a second inlet, wherein the first inlet is in fluid communication with the door passage when the door is in the closed position, and wherein the second inlet is defined above a top of the door.

3. The cooking appliance of claim 1, wherein the controller is configured to implement a delayed cooling routine in response the sensed temperature related to a cavity temperature exceeding a predefined cavity temperature for a cooking process.

4. The cooking appliance of claim 1, further comprising:
a heating element configured to heat the cooking cavity; and
a magnetron configured to generate microwaves within the cooking cavity.

5. The cooking appliance of claim 1, wherein the cooling fan is deactivated in response to the door moving to an opened position, and wherein the cooling fan is configured to draw the air from a space between an inner surface of the door and a front panel of the external enclosure when the door is in the opened position, and further wherein a fluid path between the door passage and the at least one inlet is disrupted when the door is in the opened position.

6. The cooking appliance of claim 1, wherein the controller is configured to reactivate the cooling fan at a maximum speed.

7. The cooking appliance of claim 1, wherein the controller is configured to deactivate the cooling fan in response to the sensed temperature falling below a second predefined temperature.

8. The cooking appliance of claim 1, wherein the controller is configured to actively control the cooling fan in response to the sensed temperature, and wherein the sensed temperature is correlated to a center cavity temperature of the cooking cavity.

9. A combination cooking appliance, comprising:
an external enclosure defining a first inlet and a second inlet;
an internal housing defining a cooking cavity, wherein an electronics area is defined between the external enclosure and the internal housing proximate to the first and second inlets;
at least one cooking component operably coupled with the cooking cavity;
a door operably coupled with the external enclosure, wherein the door defines a door inlet and a door outlet, the door outlet in selective fluid communication with the first inlet;
a cooling fan disposed within the electronics area;
a temperature sensor disposed within the electronics area; and
a controller communicatively coupled with the cooling fan, wherein the controller is configured to:
at least one of deactivate the cooling fan and retain the cooling fan in an inactive state in response to the door moving to an opened position;
receive a sensed temperature from the temperature sensor;
activate the cooling fan when the sensed temperature exceeds a first predefined temperature with the door in the opened position; and
deactivate the cooling fan when the sensed temperature reaches a second predefined temperature.

10. The combination cooking appliance of claim 9, wherein the controller is configured to:
activate the cooling fan to form a ventilation path from a surrounding environment through the second inlet and from a door passage through the first inlet when the door is in a closed position.

11. The combination cooking appliance of claim 10, wherein the cooling fan is configured to draw air directly from the surrounding environment and through the first inlet when the door is in the opened position.

12. The combination cooking appliance of claim 9, wherein the controller is configured to:
deactivate the cooling fan when the sensed temperature falls below the second predefined temperature.

13. The combination cooking appliance of claim 9, wherein the electronics area is defined between a top of the internal housing and a top panel of the external enclosure.

14. The combination cooking appliance of claim 9, wherein the controller is configured to:
actively control the cooling fan based on the sensed temperature with the door in the opened position.

15. The combination cooking appliance of claim 14, wherein the predefined temperature is based on a correlation between the cooking cavity and the sensed temperature.

16. A method of controlling ventilation of a cooking appliance, comprising:
heating a cooking cavity;
activating a cooling fan in response to a temperature of the cooking cavity exceeding a predefined cavity temperature;
drawing air through a door passage, through an inlet, and into an electronics area with the cooling fan when a door is in a closed position;
deactivating the cooling fan in response to the door moving to an opened position; and
reactivating the cooling fan in response to a sensed temperature related to a cavity temperature from a temperature sensor within the electronics area exceeding a predefined temperature with the door in the opened position.

17. The method of claim 16, further comprising:
deactivating the cooling fan when the sensed temperature falls below a second predefined temperature.

18. The method of claim 16, further comprising:
drawing air through the inlet from a space between an inner surface of the door and a front panel of an external enclosure when the door is in the opened position, wherein the door passage is free of the air directed by the cooling fan when in the opened position.

19. The method of claim 16, further comprising:
directing the air through the electronics area and through an internal passage between an external enclosure and an internal housing to expel the air from the external enclosure via an outlet at a bottom portion of the external enclosure.

20. The method of claim 16, wherein the step of reactivating the cooling fan in response to the sensed temperature includes reactivating the cooling fan at a maximum speed.
